(19) United States
(12) Patent Application Publication
(10) Pub. No.: US 2024/0355732 A1
(43) Pub. Date: Oct. 24, 2024

(54) MEMORY DEVICE AND METHOD OF FABRICATING THE SAME

(71) Applicant: MACRONIX International Co., Ltd., Hsinchu (TW)

(72) Inventors: Chen-Yu Cheng, Hsinchu City (TW); Chih-Kai Yang, Kaohsiung City (TW); Tzung-Ting Han, Hsinchu City (TW)

(73) Assignee: MACRONIX International Co., Ltd., Hsinchu (TW)

(21) Appl. No.: 18/302,804

(22) Filed: Apr. 19, 2023

(51) Int. Cl. H01L 23/528; H01L 23/522; H10B 41/10; H10B 41/27; H10B 41/35; H10B 43/10; H10B 43/27; H10B 43/35

(52) U.S. Cl. CPC H01L 23/5283; H01L 23/5226; H10B 41/10; H10B 41/27; H10B 41/35; H10B 43/10; H10B 43/27; H10B 43/35

(57) ABSTRACT

A memory device includes first and second interconnect structures, a stacked structure, a stop layer and channel pillar structures over a substrate. The stacked structure is located between the first and the second interconnection structures. The stop layer is located between the stacked structure and the second interconnect structure. Each channel pillar structure includes a channel pillar, a first channel plug and a second channel plug. The channel pillar extends through the stacked structure and the stop layer. The first channel plug is located at a first end of the channel pillar and connected to the first interconnection structure. The second channel plug is located at a second end of the channel pillar and connected to the second interconnection structure. A bottom surface of the second channel plug is closer to the substrate than a bottom surface of the stop layer.

### BACKGROUND

### Technical Field

The embodiments of the present disclosure relate to a semiconductor device and a method of fabricating the same, and particularly to a memory device and a method of fabricating the same.

### Description of Related Art

A non-volatile memory device (e.g., a flash memory) has the advantage that stored data does not disappear at power-off, so it becomes a widely used memory device for a personal computer or other electronic equipment.

Currently, the flash memory arrays commonly used in the industry include a NOR flash memory and a NAND flash memory. The NAND flash memory has multiple memory cells connected in series, so the NAND flash memory has better integration and area utilization than the NOR flash memory, and has been widely used in various electronic products. In addition, in order to further enhance the integration of memory devices, a 3-dimensional NAND flash memory has been developed. However, there are still many challenges associated with a 3-dimensional NAND flash memory.

### SUMMARY

The disclosure provides a memory device, in which a channel plug of a vertical channel is provided with a small aspect ratio, so as to reduce the difficulty of the manufacturing process and improve the reliability of the device.

The present disclosure provides a memory device, in which a channel plug of a vertical channel is provided with dopants, and the junction of the channel plug is partially overlapped or completely overlapped with the topmost conductive layer laterally, so the gate-induced drain leakage current (GIDL) may be reduced during erasing.

A memory device according to an embodiment of the present disclosure includes a first interconnect structure, a second interconnect structure, a stacked structure, a stop layer, and channel pillar structures. The first interconnect structure is located over a substrate. The second interconnect structure is located over the first interconnect structure. The stacked structure is located between the first interconnect structure and the second interconnect structure, wherein the stacked structure includes a plurality of conductive layers and a plurality of insulating layers stacked alternately. The stop layer is located between the stacked structure and the second interconnect structure. The channel pillar structures extend through the stacked structure, and each channel pillar structure includes a channel pillar extending through the stacked structure and the stop layer, a first channel plug located at a first end of the channel pillar and connected to the first interconnect structure, and a second channel plug located at a second end of the channel pillar and connected to the second interconnect structure. A bottom surface of the second channel plug is closer to the substrate than a bottom surface of the stop layer.

A method of fabricating a memory device according to an embodiment of the present disclosure includes the following steps. A stacked structure is formed on a first surface of a stop layer, wherein the stacked structure includes a plurality of intermediate layers and a plurality of insulating layers stacked alternately. Portions of the intermediate layers are replaced with a plurality of conductive layers. Channel pillar structures are formed to extend through the stacked structure, wherein forming each channel pillar structure includes forming a channel pillar extending through the stacked structure and the stop layer, forming an insulating pillar in an inner surface of the channel pillar, forming a first channel plug at a first end of the channel pillar, removing a portion of the insulating pillar at a second end of each channel pillar to form a recess, and forming a second channel plug in the recess at the second end of each channel pillar. Charge storage structures are formed on outer surfaces of the channel pillar structures.

Based on the above, in the memory device of the embodiments of the present disclosure, the aspect ratio of a channel plug of a vertical channel is small, so the difficulty of the manufacturing process may be reduced when forming the recess for the channel plug, and the reliability of the device may be improved. The channel plug of the vertical channel has dopants, and the junction of the channel plug is partially overlapped or completely overlapped with the topmost conductive layer laterally, so the gate-induced drain leakage current (GIDL) may be reduced during erasing.

### BRIEF DESCRIPTION OF THE DRAWINGS

FIG. 1A to FIG. 1Q are schematic cross-sectional views of a method of fabricating a memory device according to an embodiment of the present disclosure.

FIG. 2 is an enlarged view of a partial area of FIG. 1Q.

FIG. 3 to FIG. 5 are schematic cross-sectional views of several memory devices according to other embodiments of the present disclosure.

### DESCRIPTION OF THE EMBODIMENTS

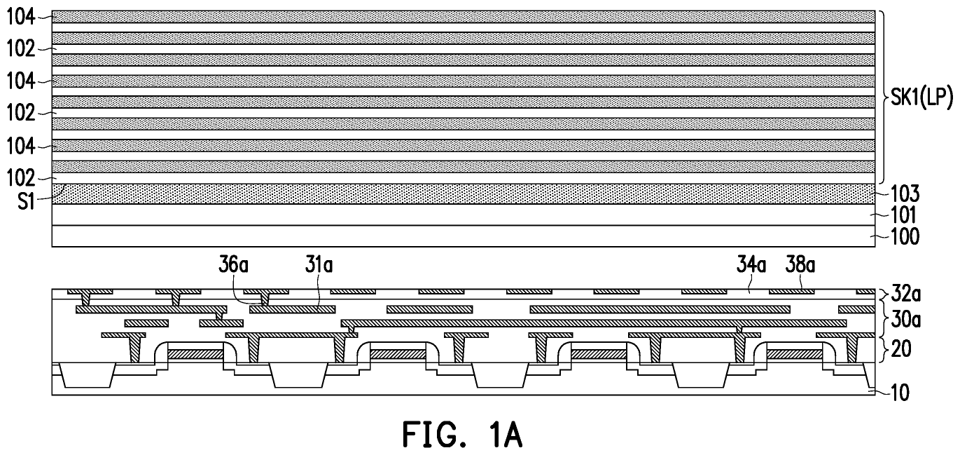

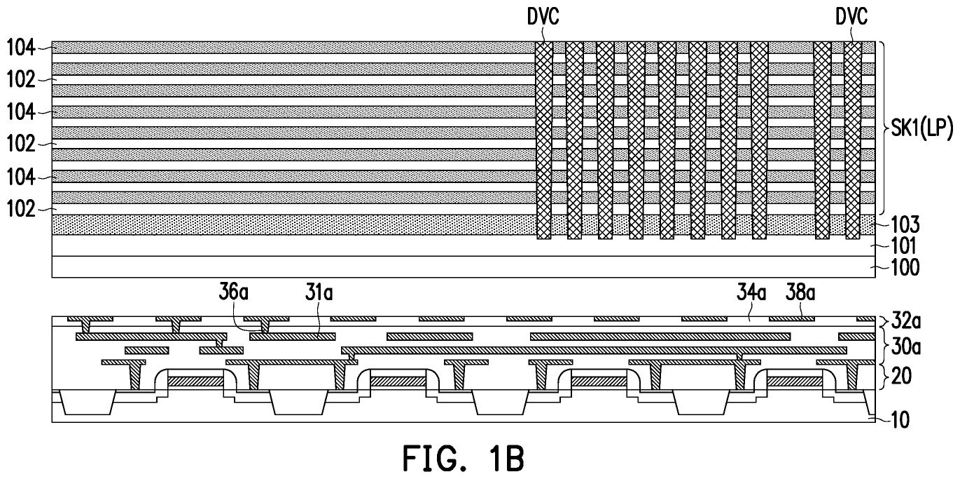

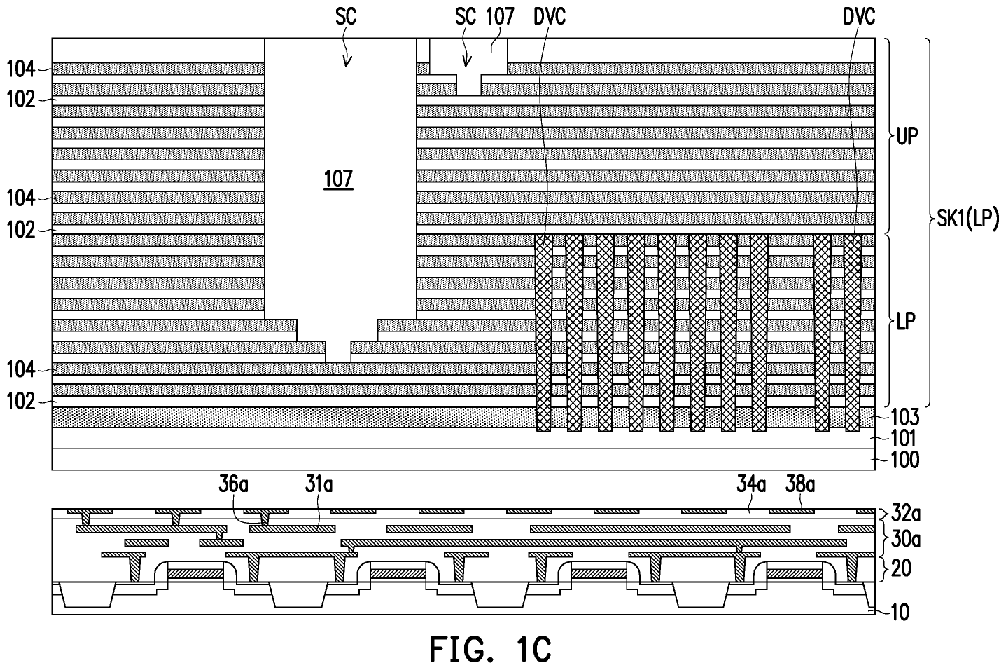

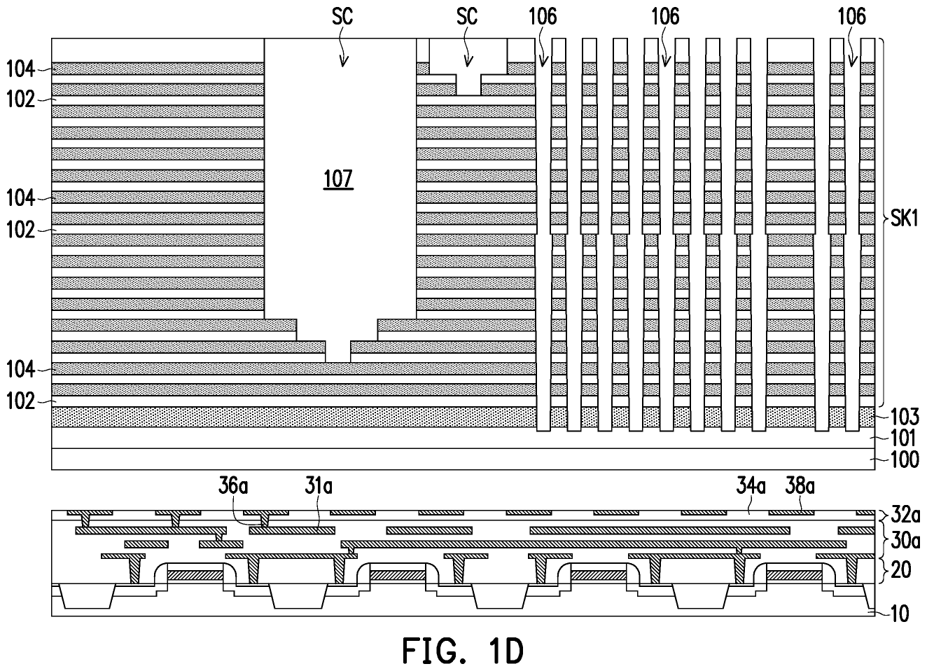

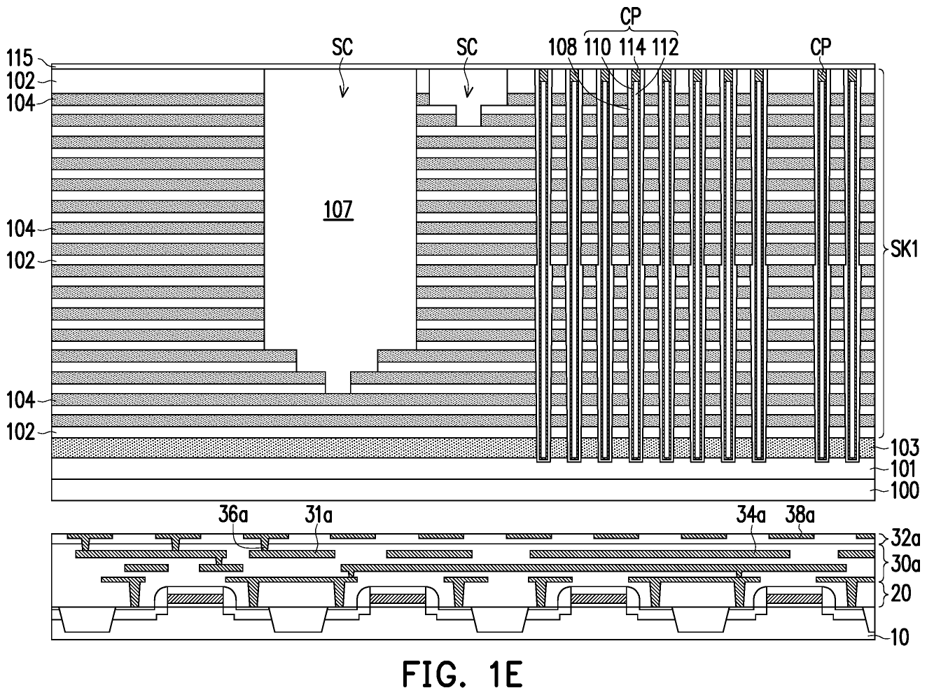

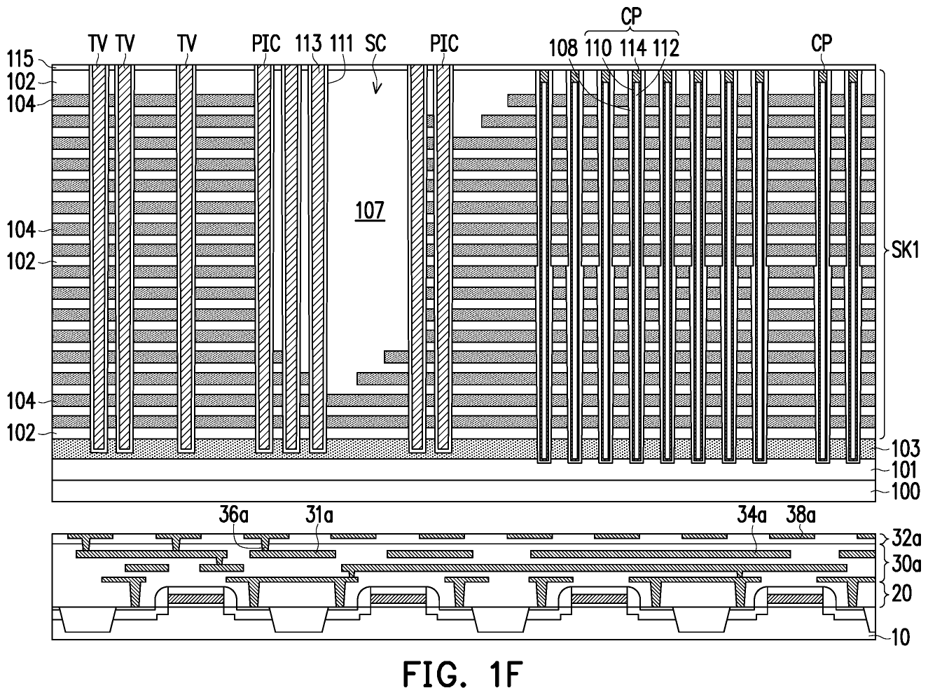

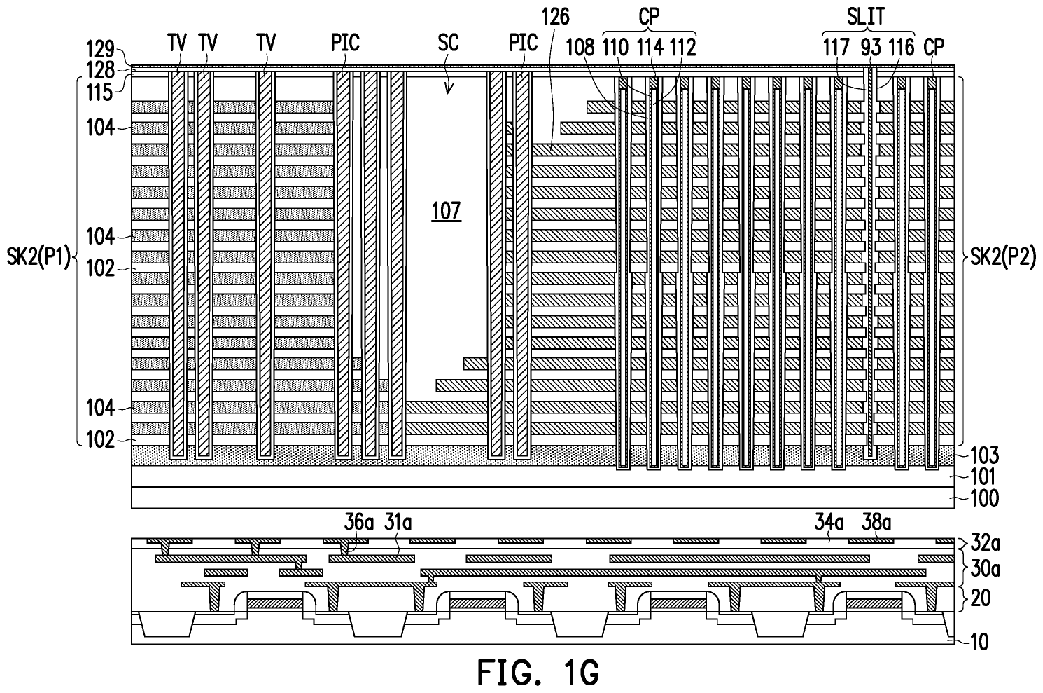

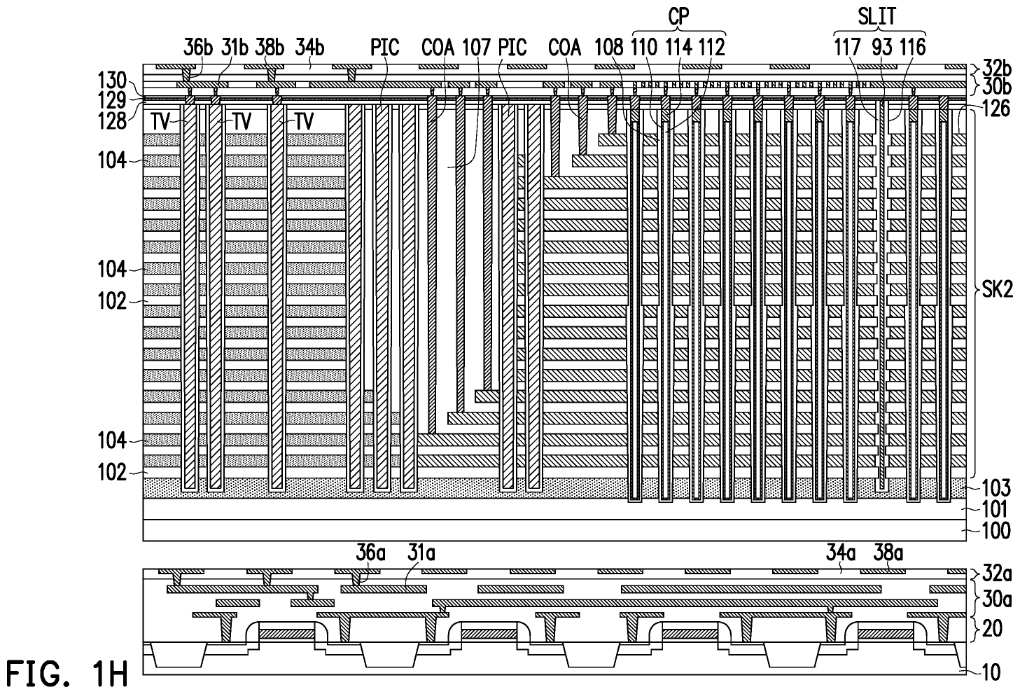

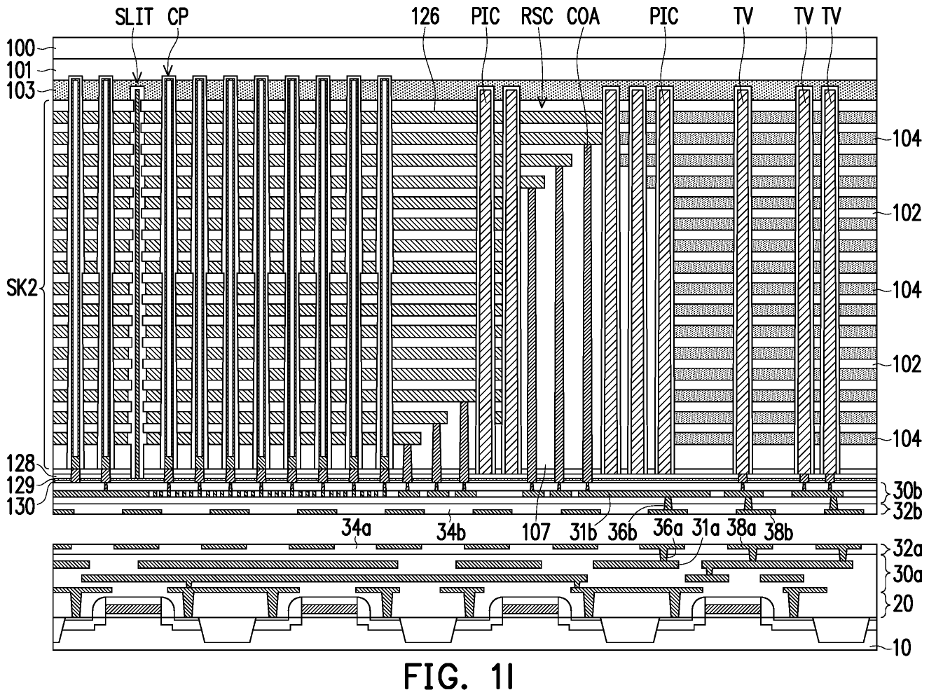

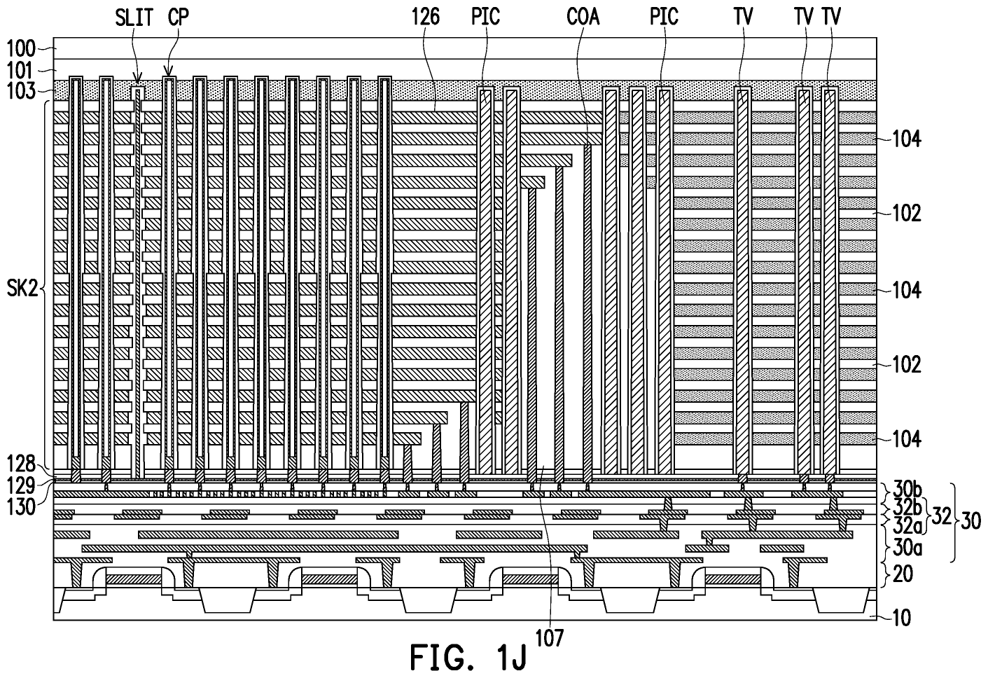

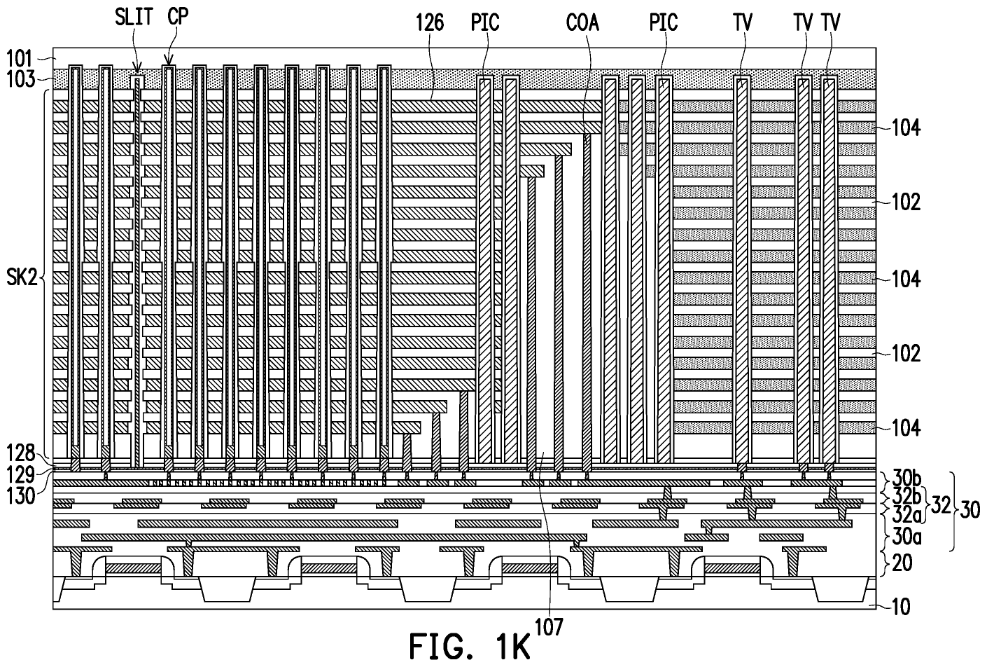

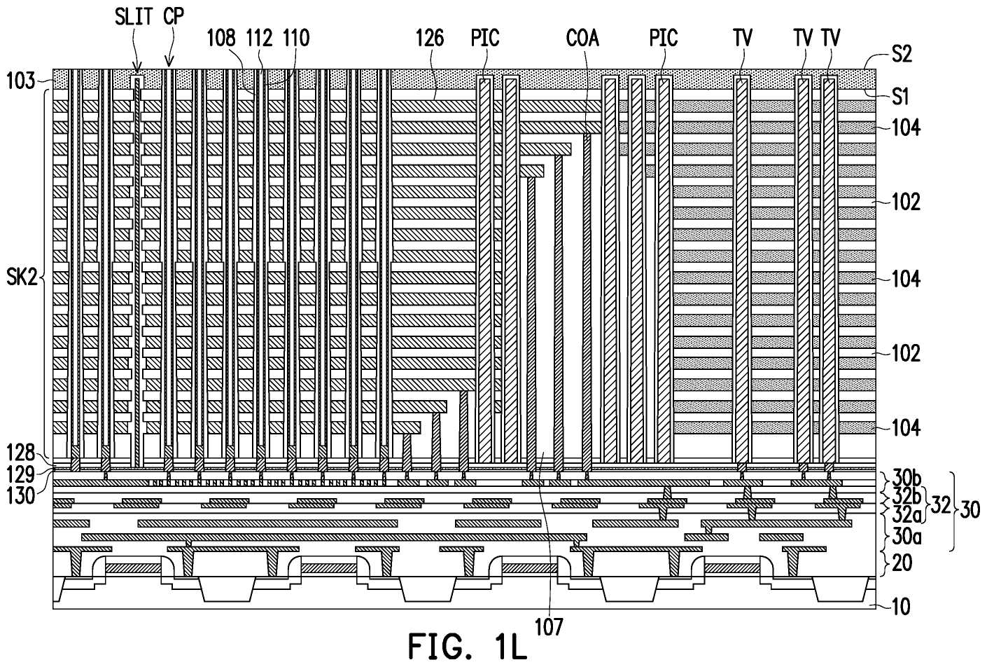

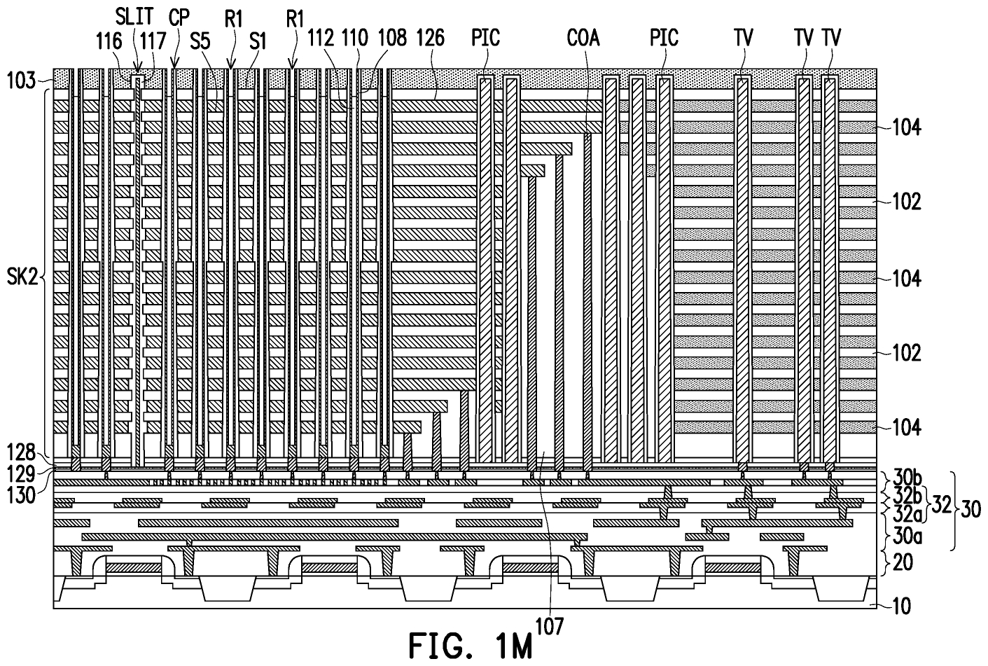

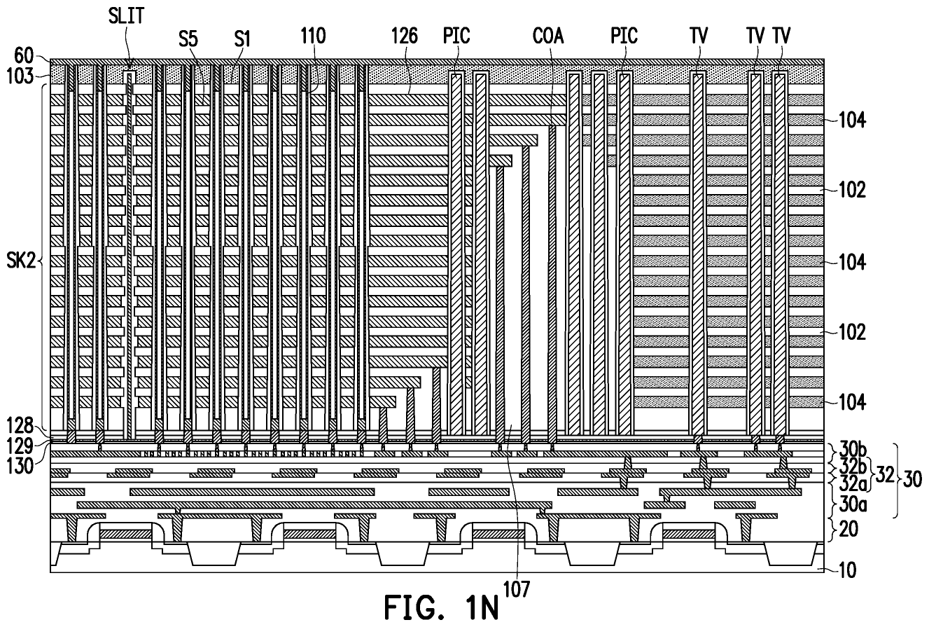

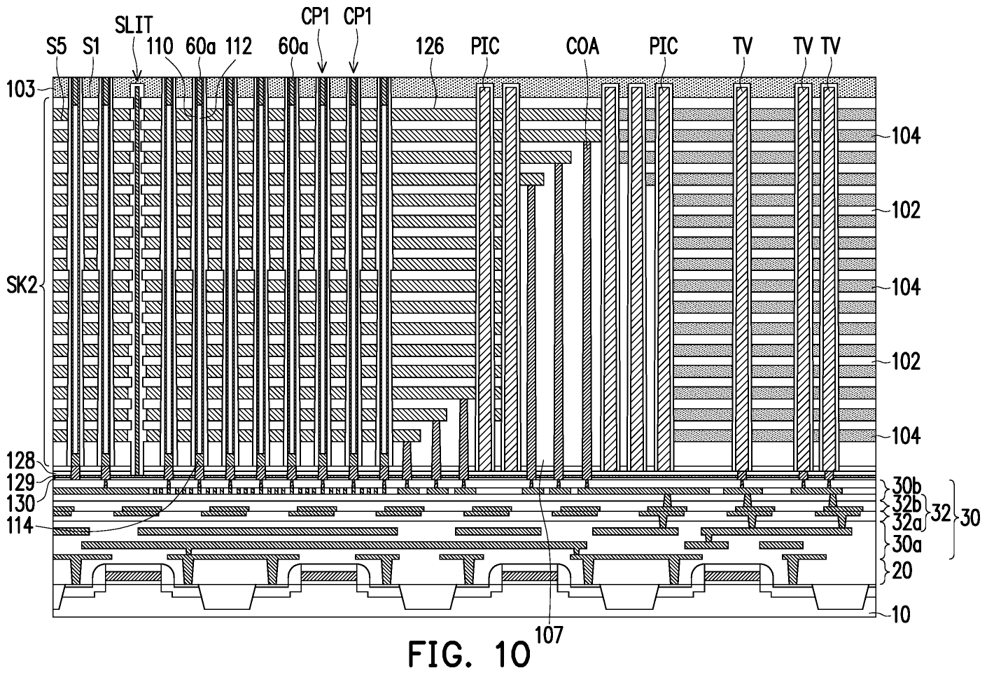

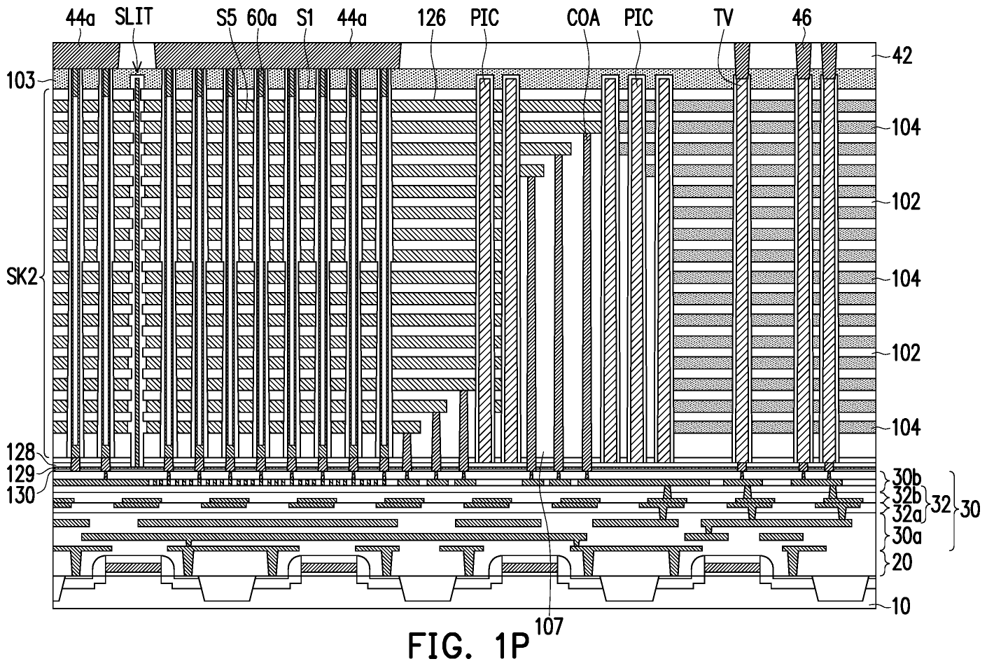

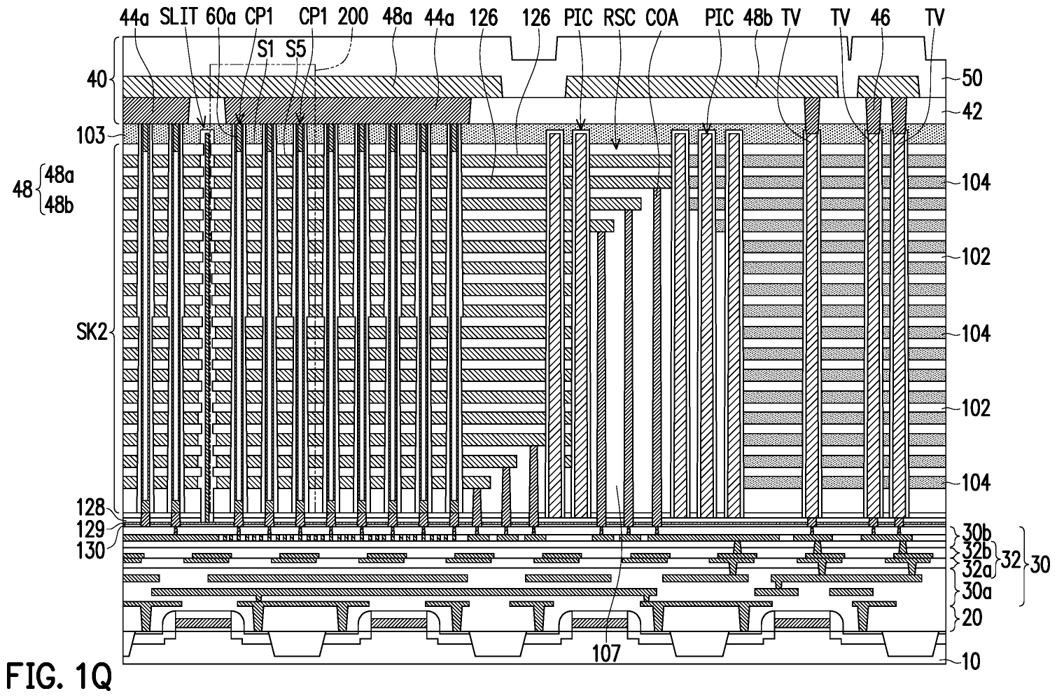

FIG. 1A to FIG. 1Q are schematic cross-sectional views of a method of fabricating a memory device according to an embodiment of the present disclosure.

Referring to FIG. 1A, a substrate 10 is provided. The substrate 10 may be a semiconductor substrate, such as a silicon-containing substrate. A device layer 20 is formed on the substrate 10. The device layer 20 may include active elements or passive elements. The active elements may include transistors, diodes, or the like. The passive elements may include capacitors, inductors, or the like. The transistors may include an N-type metal oxide semiconductor (NMOS) transistor, a P-type metal oxide semiconductor (PMOS) transistor or a complementary metal oxide semiconductor device (CMOS). The device layer 20 is formed under a memory array (e.g., located under the stacked structure SK2 in FIG. 1Q), and the device layer 20 is, for example, a complementary metal-oxide-semiconductor (CMOS), and thus, this architecture can also be called a complementary metal-oxide-semiconductor bonded the memory array (CMOS-Bonded-Array, CbA) structure.

Referring to FIG. 1A, a first portion 30a of an interconnect structure 30 is formed on the device layer 20. The first portion 30a of the interconnect structure 30 may include multiple dielectric layers (not shown) and interconnect layers (not shown) formed in the multiple dielectric layers. The interconnect layers include multiple plugs (not shown), multiple conductive lines (not shown) or the like. A dielectric layer separates adjacent conductive lines from each other. The conductive lines may be connected by plugs, and the conductive lines may be connected to the device layer 20 by plugs. The first portion 30a of the interconnect structure 30 may be formed by a single damascene process, a dual damascene process, or any known method.

Referring to FIG. 1A, a first portion 32a of a bonding structure 32 (shown in FIG. 1J) is formed on the first portion 30a of the interconnect structure 30. The first portion 32a of the bonding structure 32 includes a bonding layer 34a, a bonding plug 36a and a bonding pad 38a. The bonding layer 34a may include silicon oxide, silicon nitride or a combination thereof. The bonding plug 36a and the bonding pad 38a may include copper, for example. The bonding pad 38a is connected to the topmost conductive line 31a of the first portion 30a of the interconnect structure 30 through the bonding plug 36a. The bonding pad 38a and the bonding plug 36a may be formed by a single damascene or a dual damascene process. The bonding pad 38a, the bonding plug 36a, and the bonding layer 34a may be planarized through a chemical mechanical polishing process to be coplanar.

Referring to FIG. 1A, another substrate 100 is provided. The substrate 100 may be a semiconductor substrate, such as a silicon-containing substrate. An insulating layer 101 and a stop layer 103 are formed on the substrate 100. The insulating layer 101 may include silicon oxide. The stop layer 103 is formed on the insulating layer 101. The stop layer 103 may include an insulating material, such as silicon carbonitride (SiCN), silicon oxide (SiON), aluminum oxide (Al₂O₃) or a combination thereof.

Referring to FIG. 1A, a lower part LP of a stacked structure SK1 is formed on the surface S1 of the stop layer 103. The lower part LP of the stacked structure SK1 includes multiple insulating layers 102 and multiple intermediate layers 104 stacked alternately. In some embodiments, the material of the insulating layers 102 includes silicon oxide, and the material of the intermediate layers 104 includes silicon nitride. The intermediate layers 104 may serve as sacrificial layers, which will be partially or completely removed in the subsequent processes.

Referring to FIG. 1B, multiple dummy pillars DVCs penetrate through the lower part LP of the stacked structure SK1. The method of forming the multiple dummy pillars DVCs includes forming single-stage lithography and etching processes or multi-stage lithography and etching processes (not shown) to form multiple openings. The openings penetrate through the lower part LP of the stacked structure SK1 and extend to the stop layer 103, and even extend to the insulating layer 101. Then, a filling material (or a self-aligning material) is filled in the openings. The sidewall profiles of the openings formed by multi-stage lithography and etching processes may be bamboo-shaped.

Referring to FIG. 1C, an upper part UP of the stacked structure SK1 is formed over the substrate 100. The upper part UP of the stacked structure SK1 includes multiple insulating layers 102 and multiple intermediate layers 104 stacked on each other. The materials of the insulating layer 102 and the intermediate layers 104 of the upper part UP of the stacked structure SK1 are as those described above for the materials of the insulating layer 102 and the intermediate layers 104 of the lower part LP of the stacked structure SK1. Next, the intermediate layers 104 and insulating layer 102 of the stacked structure SK1 are patterned to form a stepped structure SC. In some embodiments, the stepped structure SC may be formed through a multi-stage patterning process, but the disclosure is not limited thereto. The patterning process may include processes such as lithography, etching and trimming. A dielectric layer 107 is formed over the substrate 100 to cover the stepped structure SC. The material of the dielectric layer 107 may include silicon oxide, for example. The method of forming the dielectric layer 107 includes forming a dielectric material, filling and covering the stepped structure SC. A planarization process (such as a chemical mechanical polishing process) is then performed to remove excess dielectric material.

Referring to FIG. 1D, a patterning process is performed to remove portions of the stacked structure SK1 to form openings (not shown), and the openings expose the dummy pillars DVC. Next, the dummy pillars DVC exposed by the openings are removed to form openings 106 extending through the stacked structure SK1. In one embodiment, the openings 106 may have slightly sloped sidewalls. In another embodiment, the openings 106 may have substantially vertical sidewalls (not shown). In one embodiment, the openings 106 are also called vertical channel (VC) holes. In one embodiment, the openings 106 may be formed by single-stage lithography and etching processes. In another embodiment, the openings 106 may be formed by multi-stage lithography and etching processes. The sidewall profiles of the openings 106 formed by multi-stage lithography and etching processes may be bamboo-shaped.

Referring to FIG. 1E, charge storage structures 108 are then formed in the openings 106. The charge storage structures 108 are in contact with the insulating layers 102 and the intermediate layers 104. In one embodiment, each of the charge storage structures 108 is an oxide/nitride/oxide (ONO) composite layer. The charge storage structure 108 may be a conformal layer formed on the sidewall and the bottom of each of the openings 106. Afterwards, a vertical channel pillar CP is formed in the remaining space of each of the openings 106. Each vertical channel pillar CP may be formed by the following method.

Referring to FIG. 1E, a channel layer 110 is formed on the inner sidewall and the bottom surface of the charge storage structure 108. In one embodiment, the material of the channel layer 110 includes undoped polysilicon. Next, an insulating pillar (or called core insulating pillar) 112 is formed on the inner surface of the channel layer 110. In one embodiment, the insulating pillar 112 may include silicon oxide. Afterwards, a channel plug 114 is formed in the opening 106, and the channel plug 114 is in contact with the channel layer 110. The channel plug 114 extends to a certain depth of the opening 106 from a top surface (not shown) of the topmost insulating layers 102. In one embodiment, the material of the channel plug 114 includes a doped semiconductor material, such as doped polysilicon. The channel layer 110, the insulating pillar 112 and the channel plug 114 may be collectively referred to as a vertical channel pillar CP. The vertical channel pillar CP penetrates through the stacked structure SK1 and extends to the stop layer 103, and even extends to the insulating layer 101. The charge storage structure 108 surrounds the vertical outer surface of the vertical channel pillar CP. After that, a dielectric layer 115 is formed over the substrate 100. The material of the dielectric layer 115 includes silicon oxide.

Referring to FIG. 1F, multiple support structures PIC and multiple through vias TV are formed. The support structures PIC and the through vias TV extend from the top surface of the dielectric layer 115 through the stacked structure SK1 and the stop layer 103, so as to avoid the collapse of the stepped structure SC during the subsequent removal of the intermediate layers 104. In this embodiment, the support structures PIC and the through vias TV may have the same structure, each including an insulating liner layer 111 and a conductive layer 113. In other embodiments, the support structures PIC may be formed simultaneously with the formation of the charge storage structures 108 and the vertical channel pillars CP. Each of the support structures PIC may have a structure same as the combination of a charge storage structure 108 and a vertical channel pillar CP, but the present disclosure is not limited thereto. The through vias TV will be connected to the interconnect lines in the subsequent manufacturing process, so the through vias TV can also be called signal contacts.

Referring to FIG. 1G, a dielectric layer 128 is formed on the dielectric layer 115. The dielectric layer 128 may include silicon oxide. Thereafter, a patterning process is performed to form one or more separation trenches 116. The separation trench 116 extends through the dielectric layer 128, the dielectric layer 115 and the stacked structure SK1 to divide the stacked structure SK1 into multiple blocks (not shown). The separation trench 116 may have vertical sidewalls (not shown) or slightly inclined sidewalls (not shown).

Referring to FIG. 1G, a replacement process is performed, so as to replace portions of the intermediate layers 104 with the conductive layers 126. First, a selective etching process is performed, so that the etchant passes through the separation trench 116 and therefore contacts and removes the intermediate layers 104 of the stacked structure SK1 at both sides of the separation trench 116. Thereby, portions of the intermediate layers 104 are removed to form multiple horizontal openings (not shown), while the intermediate layers 104 around the through vias TV remain. The selective etching process may be an isotropic etching process, such as a wet etching process. The etchant used in the wet etching process may include hot phosphoric acid. Then, conductive layers 126 are formed in the separation trench 116 and the horizontal openings. The conductive layers 126 may serve as gate layers. Each of the conductive layers 126 includes, for example, a barrier layer and a metal layer. In one embodiment, the material of the barrier layer includes titanium (Ti), titanium nitride (TiN), tantalum (Ta), tantalum nitride (TaN) or a combination thereof. The material of the metal layer includes tungsten (W). The portions of the intermediate layers 104 are replaced by the conductive layers 126, thus forming a stacked structure SK2.

The stacked structure SK2 includes a first part P1 and a second part P2. The first part P1 of the stacked structure SK2 includes multiple insulating layers 102 and multiple intermediate layers 104 stacked alternately. The second part P2 of the stacked structure SK2 includes multiple insulating layers 102 and multiple conductive layers 126 stacked alternately. The multiple vertical channel pillars CP extend through the second part P2 of the stacked structure SK2. The multiple through vias TV extend through the first part P1 of the stacked structure SK2. Some of the multiple support structures PIC extend through the second part P2 of the stacked structure SK2. Some of the multiple support structures PIC extend through the first part P1 of the stacked structure SK2.

Referring to FIG. 1G, the conductive layer 126 formed in the separation trench 116 is removed, and a spacer 117 is formed on the sidewall of the separation trench 116. The spacer 117 includes a dielectric material different from the insulating layer 102, such as silicon nitride or a silicon oxide/silicon nitride/silicon oxide composite layer. Afterwards, a conductive layer 93 (such as a doped polysilicon layer) is filled in a remaining space of the separation trench 116. The conductive layer 93 and the spacer 117 in the separation trench 116 together form a separation wall (or called slit) SLIT. The conductive layer 93 of the separation wall SLIT is isolated from the conductive layers 126 by the spacer 117 to avoid undesired connection with each other. Thereafter, a stop layer 129 is formed on the dielectric layer 128 to cover a top surface of the separation wall SLIT. The stop layer 129 may include silicon nitride.

Referring to FIG. 1H, a dielectric layer 130 is formed on the stop layer 129. The dielectric layer 130 may include silicon oxide. Next, multiple contacts COA are formed in the dielectric layer 130 and the dielectric layer 107 to electrically connect the conductive layer 126, the vertical channel pillar CP and the through vias TV, respectively. The method of forming the contacts COA may include forming contact holes, and then forming a conductive material on the dielectric layer 130, filling in the contact holes. Afterwards, an etch-back or a chemical-mechanical polishing process is performed to remove the conductive material on the dielectric layer 130.

Referring to FIG. 1H, a second portion 30b of the interconnect structure 30 is formed over the substrate 100. The second portion 30b of the interconnect structure 30 may include multiple dielectric layers (not shown) and interconnect layers (not shown) formed in the multiple dielectric layers. The interconnect layers include multiple plugs (not shown), multiple conductive lines (not shown) or the like. A dielectric layer separates adjacent conductive lines from each other. The conductive lines may be connected by plugs, and the conductive lines may be connected to the contacts COA by plugs. The second portion 30b of the interconnect structure 30 may be formed by a single damascene process, a dual damascene process, or any known method.

Referring to FIG. 1H, a second portion 32b of the bonding structure 32 (shown in FIG. 1J) is formed on the second portion 30b of the interconnect structure 30. The second portion 32b of the bonding structure 32 includes a bonding layer 34b, a bonding plug 36b and a bonding pad 38b. The bonding pad 38b is connected to the topmost conductive line 31b of the second portion 30b of the interconnect structure 30 through the bonding plug 36b. The materials and forming methods of the bonding layer 34b, the bonding plug 36b, and the bonding pad 38b may be the same or similar to those of the bonding layer 34a, the bonding plug 36a, and the bonding pad 38a.

Referring to FIG. 1I, the substrate 100 is turned over or flipped over. The stepped structure SC on the flipped substrate 100 becomes a reverse stepped structure RSC. The contacts COA are under the reverse stepped structure RSC. Next, referring to FIG. 1I and FIG. 1J, the second portion 32b of the bonding structure 32 is bonded to the first portion 32a of the bonding structure 32 to form a bonding structure 32. In the bonding structure 32, the bonding layer 34b is bonded to the bonding layer 34a, and the bonding pad 38b is bonded to the bonding pad 38a. The bonding layer 34b and the bonding layer 34a may be bonded by a dielectric-to-dielectric bonding. The bonding pad 38b and the bonding pad 38a may be bonded by a metal-to-metal bonding. The bonding structure 32 is located in the interconnect structure 30, and between the first portion 30a and the second portion 30b of the interconnect structure 30. The bonding structure 32, the first portion 30a and the second portion 30b constitute an interconnect structure 30.

Referring to FIG. 1K, the substrate 100 is removed to expose the insulating layer 101. The substrate 100 may be removed by grinding, polishing or etching.

Referring to FIG. 1L, an etching process is performed using the stop layer 103 as an etching stop layer, so as to remove the insulating layer 101, portions of the charge storage structures 108, and portions of the channel layers 110, and therefore expose the top surface of the insulating pillars 112 of the vertical channel pillars CP and expose the surface S2 of the stop layer 103. Herein, the channel layers 110 can also be referred to as channel pillars 110.

Referring to FIG. 1M, an etching process (such as a wet etching process) is performed to remove portions of the insulating pillars 112 to form multiple recesses R1. The material of the stop layer 103 is different from that of the insulating pillars 112, so the stop layer 103 can protect the insulating layers 102 and the underlying separation wall SLIT during the etching process. The stop layer 103 can prevent the insulating layers 102 and the spacer 117 of the separation wall SLIT from being etched and damaged. In some embodiments, each of the recesses R1 exposes the inner sidewall of the corresponding channel pillar 110 and the top surface of the remaining insulating pillar 112. In some other embodiments, a portion of each channel pillar 110 is also removed, so that the recess R1 exposes the inner sidewall of the corresponding charge storage structure 108 (not shown). Each recess R1 extends through the stop layer 103, and the bottom surface of the recess R1 is lower than the bottom surface (i.e., surface S1) of the stop layer 103. In some embodiments, the bottom surface of the recess R1 is, for example, between the bottom surface (i.e., surface S1) of the stop layer 103 and the bottom surface S5 of the topmost conductive layer 126. The depth of recess R1 may be controlled by a time-mode etching process. The aspect ratio of recess R1 is much smaller than that of the separation trench 116 of the separation wall SLIT. The aspect ratio of recess R1 is, for example, 1 to 6.25. Due to the small aspect ratio of the recess R1, the difficulty of etching may be reduced.

Referring to FIG. 1N, a channel material 60 is formed on the stop layer 103. The channel material 60 is further filled in the recesses R1 and electrically connected to the channel pillars 110. Due to the small aspect ratio of each recess R1, the channel material 60 may be easily back-filled in the recess R1. The channel material 60 may include a semiconductor material. The semiconductor material may include a semiconductor element or a semiconductor compound. The semiconductor element may include polysilicon. The semiconductor compound may include germanium silicide or silicon carbide. The channel material 60 has dopants. The dopants may include phosphorous or arsenic. The concentration of dopants may range from 1E18 to 1E21 atoms/cubic centimeter.

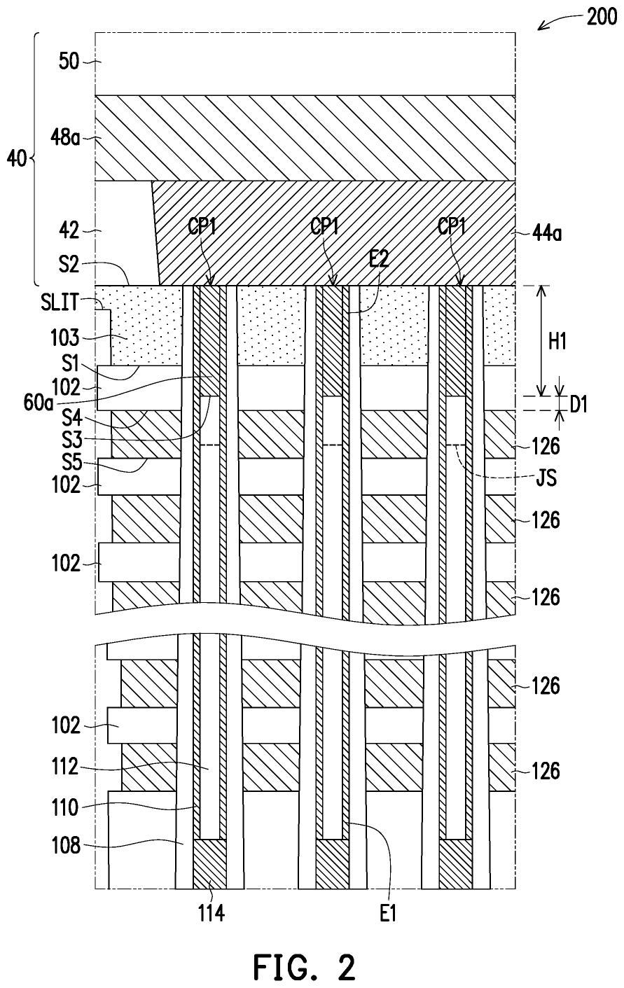

Referring to FIG. 1O and FIG. 2, a planarization process is performed to remove the channel material 60 on the stop layer 103, and therefore form channel plugs 60a electrically connected to the channel pillars 110 in the recesses R1. In some embodiments, the dopants of the channel material 60 may be formed by in-situ doping when the channel material is deposited. The temperature of the deposition process may be lower than 450 degrees Celsius. In some other embodiments, the dopants of the channel material 60 may be formed through an ion implantation process, and then activated by an annealing process. The annealing process may include a laser annealing. The temperature of the annealing process is lower than 450 degrees Celsius. After the annealing, the junction JS (shown in FIG. 2) formed by dopant diffusion can be fully or partially overlapped with the topmost conductive layer 126 laterally.

Referring to FIG. 1O and FIG. 2, the channel plug 60a, the channel pillar 110, the insulating pillar 112 and the channel plug 114 may be collectively referred to as a channel pillar structure CP1. The channel pillar structure CP1 extends through multiple insulating layers 102 and multiple conductive layers 126 of the stacked structure SK2. The two ends (top and bottom ends) E2 and E1 of each channel pillar structure CP1 are respectively provided with channel plugs 60a and 114, which may be connected to other conductive features, such as the corresponding conductive pad 44a (shown in FIG. 1P and FIG. 2) and the corresponding contact COA. Therefore, the channel pillar structure CP1 can also be called a double-ended vertical channel pillar. The charge storage structure 108 surrounds the channel plug 60a, the channel pillar 110 and the outer sidewall of the channel plug 114 of the channel pillar structure CP1, and is located between the channel pillar structure CP1 and the corresponding conductive layer 126, and is located between the channel pillar structure CP1 and the corresponding insulating layer 102.

Referring to FIG. 1P, a dielectric layer 42, contacts 46 and conductive pads 44a of an interconnect structure 40 (shown in FIG. 1Q) are formed on the stop layer 103. The contacts 46 are electrically connected to the through vias TV. The multiple channel plugs 60a of multiple channel pillar structures CP1 are electrically connected to the same conductive pad 44a. The dielectric layer 42 may have a single-layer or multilayer structure. The material of the dielectric layer 42 may include silicon oxide, silicon oxynitride, silicon nitride or a combination thereof. The contacts 46 and conductive pads 44a are formed in dielectric layer 42. The method of forming the contacts 46 and the conductive pads 44a is as follows. First, contact holes (not shown) and conductive pad openings (not shown) are formed in the dielectric layer 42 through lithography and etching processes. Then, a conductive material is formed on the dielectric layer 42, filling into the contact holes and the conductive pad openings. Thereafter, a planarization process (such as a chemical mechanical polishing process) is performed to remove the excess conductive material on the dielectric layer 42 and therefore form contacts 46 and conductive pads 44a in the contact holes and the conductive pad openings.

Referring to FIG. 1Q, another portion of the interconnect structure 40 (including conductive lines 48 and a dielectric layer 50) is formed on the dielectric layer 42, the conductive pads 44a and the contacts 46. The conductive lines 48 may include conductive lines 48a and 48b. The conductive line 48a may serve as a common source line to connect the conductive pads 44a. The adjacent conductive pads 44a may be electrically connected to the same conductive line 48a. The conductive line 48b may be connected to the contacts 46. The material of the conductive lines 48 may include copper or tungsten, for example. The dielectric layer 50 may have a single-layer or multilayer structure. The material of the dielectric layer 42 may include silicon oxide, silicon oxynitride, silicon nitride or a combination thereof. The interconnect structure 40 may be electrically connected to the interconnect structure 30 by the through vias TV. The interconnect structure 40 may be electrically connected to the interconnect structure 30 by the contacts COA. The interconnect structure 40 may be electrically connected to the interconnect structure 30 by the channel pillar structures CP1.

FIG. 2 is an enlarged view of the local area 200 of FIG. 1Q.

Referring to FIG. 2, charge storage structures 108 are located on the outer surfaces of channel pillar structures CP1. The multiple channel plugs 60a of the multiple channel pillar structures CP1 extend through the stop layer 103 and at least a portion of the topmost insulating layer 102. The height H1 of the multiple channel plugs 60a is greater than the thickness T1 of the stop layer 103. The bottom surface S3 of each channel plugs 60a is closer to the substrate 10 (shown in FIG. 1Q) than the bottom surface (i.e., surface S1) of the stop layer 103. That is, the bottom surface S3 of each channel plug 60a may be lower than the bottom surface (i.e., surface S1) of the stop layer 103. The bottom surface S3 of the channel plug 60a may be higher than the top surface S4 of the topmost conductive layer 126. Alternatively, the bottom surface S3 of the channel plugs 60a may be lower than the bottom surface (i.e., surface S1) of the stop layer 103, and lower than the top surface S4 of the topmost conductive layer 126. In some embodiments, the bottom surface S3 of the channel plug 60a is between the top surface S4 and the bottom surface of the topmost conductive layer 126. Since each channel plug 60a has dopants, the junction can be partially or completely overlapped with the topmost conductive layer 126 laterally, so the gate-induced drain leakage (GIDL) may be reduced during erasing. In some embodiments, the height H1 of the channel plug 60a from the top surface S2 of the stop layer 103 to the bottom surface S3 of the channel plug 60a is in a range from 500 angstroms to 1,500 angstroms. An aspect ratio of the channel plug 60a is in a range from 0.5 to 3.75, for example. The distance D1 between the bottom surface S3 of each channel plug 60a and the top surface S4 of the topmost conductive layer 126 is in a range from −300 angstroms to 300 angstroms.

Referring to FIG. 1Q and FIG. 2, in the above-mentioned embodiments, multiple channel plugs 60a of multiple channel pillar structures CP1 are formed in the stop layer 103 and separated from each other by the stop layer 103. Multiple adjacent channel plugs 60a are electrically connected to each other locally through a conductive pad 44a (conductive feature) formed in the dielectric layer 42. The conductive pads 44a at opposite sides of the separation wall SLIT are electrically connected through a conductive line (common source line) 48a. However, the present disclosure is not limited thereto. The conductive feature connected to adjacent channel plugs 60a may be formed before or after the dielectric layer 42 is formed, and may be located in, below or above the dielectric layer 42.

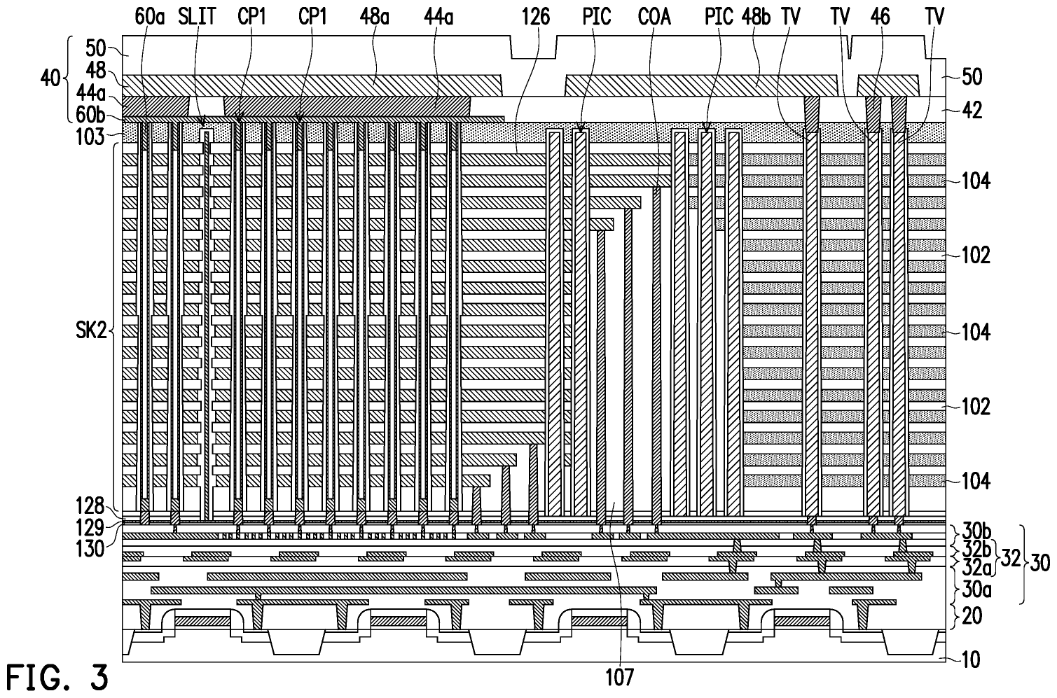

FIG. 3 to FIG. 5 are schematic cross-sectional views of several memory devices according to other embodiments of the present disclosure.

Referring to FIG. 1N and FIG. 3, after forming the channel material 60 on the stop layer 103 and in the recesses R1 (shown in FIG. 1M), before forming the dielectric layer 42, the channel material 60 is patterned to replace the planarization process. The patterning process of the channel material 60 may be performed by lithography and etching processes. The channel material 60 on multiple support structures PIC and multiple through vias TV has been removed. The channel material 60 is patterned into a semiconductor pad 60b (conductive feature) on the stop layer 103, and channel plugs 60a filled in the recesses R1. The adjacent channel plugs 60a are electrically connected to each other through the same semiconductor pad 60b. The semiconductor pad 60b (conductive feature) is further connected to multiple channel plugs 60a at opposite sides of the separation wall SLIT. Thereafter, as described in the above-mentioned embodiments, a dielectric layer 42, conductive pads 44a, conductive lines 48, and a dielectric layer 50 of an interconnect structure 40 are formed.

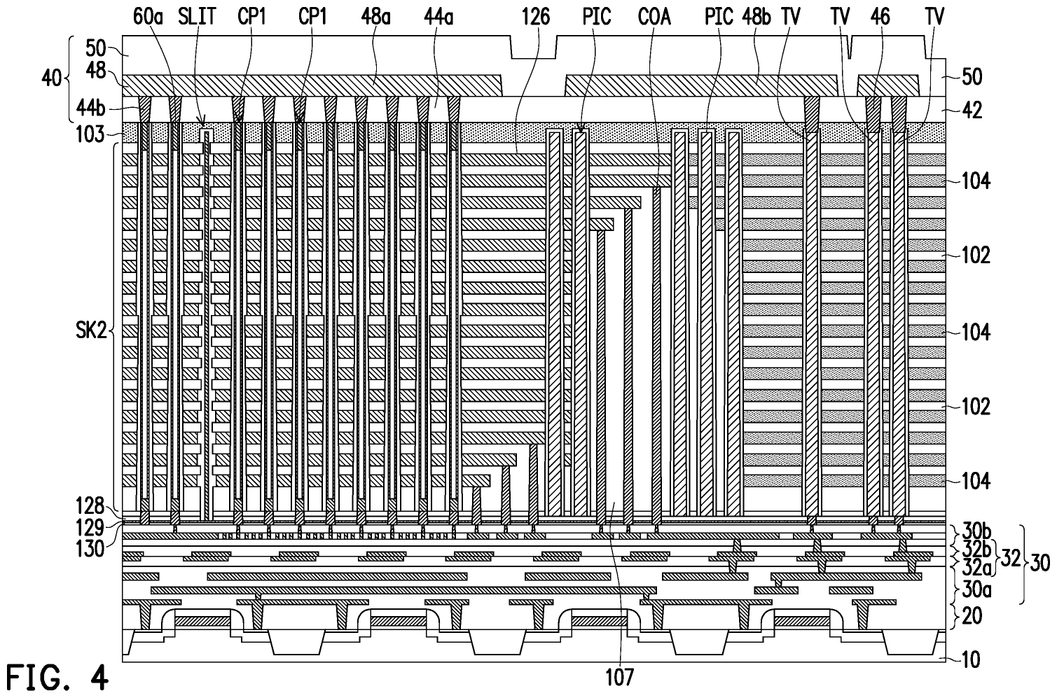

Referring to FIG. 1P and FIG. 4, after the dielectric layer 42 is formed on the stop layer 103, multiple contacts 46 and multiple vias 44b separated from each other are formed in the dielectric layer 42. The contacts 46 are connected to the through vias TV. Each via 44b is connected to a single channel plug 60a. The multiple vias 44b are electrically connected to each other by a subsequently formed conductive line (common source line) 48a. The multiple adjacent vias 44b may be electrically connected to the same conductive line 48a.

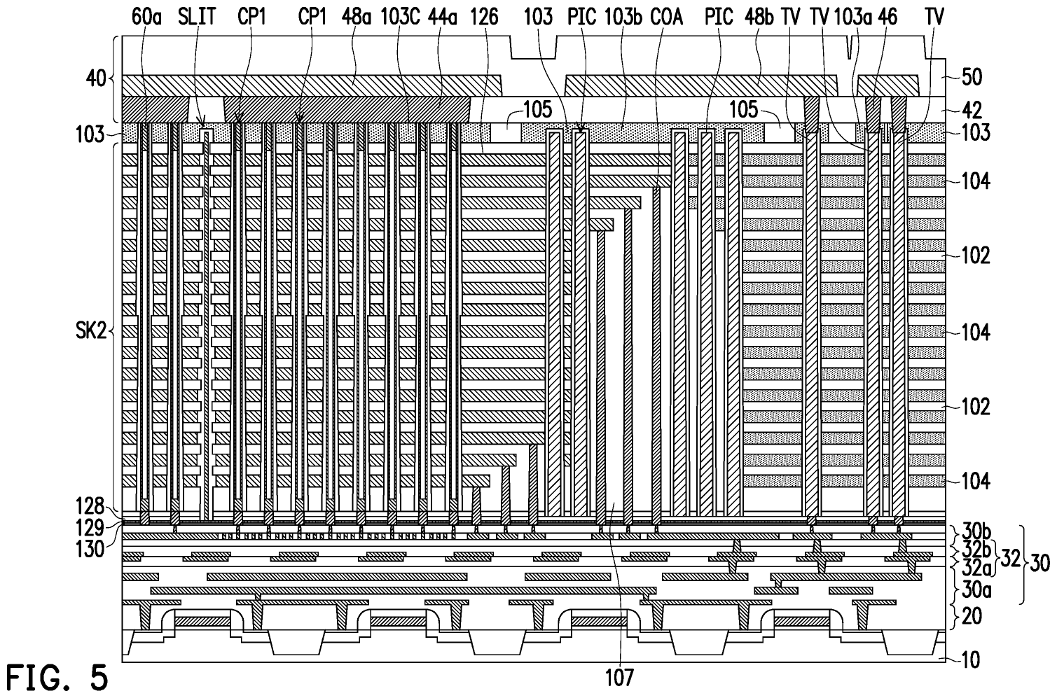

Referring to FIG. 1Q to FIG. 4, the above stop layer 103 is an insulating continuous layer, however, the present disclosure is not limited thereto. The stop layer 103 can also be a discontinuous patterned conductive layer as shown in FIG. 5.

Referring to FIG. 5, the material of the patterned conductive layer may include polysilicon layer or tungsten, for example. The conductive patterns of the patterned conductive layer are separated by a dielectric layer 105. The method of forming the stop layer 103 and the dielectric layer 105 may include forming a dielectric layer 105 followed by a stop layer 103 formed with a damascene method. The damascene method includes forming a dielectric layer 105, and then patterning the dielectric layer 105 to form multiple openings. Thereafter, a stop material is formed on the dielectric layer 105, filling the multiple openings. Then, a planarization process (such as a chemical mechanical polishing process) is performed to remove excess stop material on the dielectric layer 105 to form the stop layer 103. Alternatively, the method of forming the stop layer 103 and the dielectric layer 105 may include forming a stop material, and then patterning the stop material to form the stop layer 103. Afterwards, a dielectric material is formed on and around the stop layer 103. Then, a planarization process (such as a chemical mechanical polishing process) is performed to remove the dielectric material on the stop layer 103 to form the dielectric layer 105.

Referring to FIG. 5, in this embodiment, the stop layer 103 is a discontinuous patterned conductive layer. The material of the patterned conductive layer may include polysilicon layer or tungsten, for example. The stop layer 103 may include conductive patterns 103a, 103b and 103c. The conductive patterns 103a, 103b and 103c are electrically insulated from each other by the dielectric layer 105. Each of the conductive patterns 103a surrounds one of the through vias TV. The conductive pattern 103b surrounds the multiple support structures PIC. Each of the conductive patterns 103c surrounds one of the multiple channel plugs 60a.

The multiple through vias TV are electrically connected to the stop layer 103 (conductive patterns 103a) respectively, and are electrically insulated from each other by the dielectric layer 105. The multiple support structures PIC may be connected to the same stop layer 103 (conductive pattern 103a). The multiple support structures PIC are electrically insulated from the adjacent through vias TV by the dielectric layer 105. The multiple support structures PIC are electrically insulated from the adjacent channel plugs 60a by the dielectric layer 105. The stop layer 103 (conductive patterns 103a) around the multiple channel plugs 60a extends continuously from one side of the separation wall SLIT to the other side along a horizontal direction. Therefore, the multiple channel plugs 60a at opposite sides of the separation wall SLIT are electrically connected to each other through the conductive pad 44a and the underlying stop layer 103, and may also be electrically connected to each other through the conductive pads 44a and the overlying conductive lines 48.

In summary, the embodiment of the present disclosure forms a memory device by bonding two wafers. One of the wafers has a stop layer, which can protect the stacked structure under the stop layer during the etching process. Channel plugs on tops of the vertical channel pillars may be formed by etching recesses and then backfilling the channel material. Afterwards, conductive features are formed on the channel plugs, so that multiple channel plugs are electrically connected to each other. Due to the small aspect ratio of the recesses, the recesses may be easily etched and the channel material may be easily backfilled. Therefore, the difficulty of the manufacturing process may be reduced with the method of the embodiment of the present disclosure. Each channel plug has dopants, and the junction can be partially overlapped or completely overlapped with the topmost conductive layer laterally, so the gate-induced drain leakage (GIDL) may be reduced during erasing.

What is claimed is:

1. A memory device, comprising:
a first interconnect structure located over a substrate;
a second interconnect structure located over the first interconnect structure;
a stacked structure located between the first interconnect structure and the second interconnect structure, wherein the stacked structure comprises a plurality of conductive layers and a plurality of insulating layers stacked alternately;
a stop layer located between the stacked structure and the second interconnect structure; and
a plurality of channel pillar structures extending through the stacked structure, each channel pillar structure comprising:
a channel pillar extending through the stacked structure and the stop layer;
a first channel plug located at a first end of the channel pillar and connected to the first interconnect structure; and
a second channel plug located at a second end of the channel pillar and connected to the second interconnect structure,
wherein a bottom surface of the second channel plug is closer to the substrate than a bottom surface of the stop layer.

2. The memory device according to claim 1, wherein the second channel plug extends through the stop layer and at least a portion of a topmost insulating layer of the plurality of insulating layers.

3. The memory device according to claim 1, wherein the bottom surface of the second channel plug is located between the bottom surface of the stop layer and a bottom surface of a topmost conductive layer of the plurality of conductive layers.

4. The memory device according to claim 1, wherein the first channel plug and the second channel plug comprise semiconductor materials with dopants.

5. The memory device according to claim 1, wherein adjacent second channel plugs are electrically connected to each other through a semiconductor pad.

6. The memory device according to claim 1, wherein adjacent second channel plugs are connected to the same conductive pad of the second interconnect structure, and then connected to a common source line.

7. The memory device according to claim 1, wherein adjacent second channel plugs are connected to multiple vias of the second interconnect structure, and then connected to a common source line.

8. The memory device according to claim 1, further comprising a bonding structure located in the first interconnect structure.

9. The memory device according to claim 1, wherein a height of the second channel plug from a top surface of the stop layer is in a range from 500 angstroms to 1500 angstroms.

10. The memory device according to claim 1, wherein an aspect ratio of the second channel plug is in a range from 0.5 to 3.75.

11. The memory device according to claim 1, wherein a distance between a bottom surface of the second channel plug and a top surface of a topmost conductive layer of the plurality of conductive layers is in a range from −300 angstroms to 300 angstroms.

12. The memory device according to claim 1, further comprising:
a plurality of through vias, extending through the stop layer and through intermediate layers and the insulating layers of the stacked structure stacked alternately, and connected to the first interconnect structure and the second interconnect structure.

13. The memory device according to claim 1, wherein the stop layer comprises an insulating material or a patterned conductive layer.

14. A method of fabricating a memory device, comprising:
forming a stacked structure on a first surface of a stop layer, wherein the stacked structure comprises a plurality of intermediate layers and a plurality of insulating layers stacked alternately;
replacing portions of the intermediate layers with a plurality of conductive layers;
forming a plurality of channel pillar structures extending through the stacked structure, wherein forming each channel pillar structure comprises:
forming a channel pillar extending through the stacked structure and the stop layer;
forming an insulating pillar in an inner surface of the channel pillar;
forming a first channel plug at a first end of the channel pillar;
removing a portion of the insulating pillar at a second end of each channel pillar to form a recess; and
forming a second channel plug in the recess at the second end of each channel pillar; and
forming charge storage structures on outer surfaces of the channel pillar structures.

15. The method according to claim 14, further comprising:
performing an ion implantation process to implant dopants into the second channel plug; and
performing an annealing process to activate the dopants.

16. The method according to claim 14, further comprising:
forming a first portion of a first interconnect structure over a first substrate;
forming a first portion of a bonding structure over the first portion of the first interconnect structure;
forming a second portion of the first interconnect structure over the stacked structure and connected to the first channel plug;
forming a second portion of the bonding structure over the second portion of the first interconnect structure; and
bonding the first portion of the bonding structure to the second portion of the bonding structure.

17. The method according to claim 16, further comprising:
forming the stop layer on a second substrate;
removing the second substrate, and exposing the second end of each channel pillar; and
forming a second interconnect structure over a second surface of the stop layer and connected to the second channel plug,
wherein a bottom surface of the second channel plug is closer to the first substrate than the first surface of the stop layer.

18. The method according to claim 17, wherein a method of forming the second channel plug of each channel pillar structure comprises:
forming a channel material on the second surface of the stop layer and in the recess; and
removing the channel material on the second surface of the stop layer to form the second channel plug in the recess.

19. The method according to claim 18, wherein forming the second interconnect structure comprises forming a conductive pad or a via connected to the second channel plug.

20. The method according to claim 17, wherein a method of forming the second channel plug in the recess of each channel pillar structure comprises:
forming a channel material on the second surface of the stop layer and in the recess; and
patterning the channel material on the second surface of the stop layer to form a semiconductor layer, and forming the second channel plug in the recess.
